(19) United States
(12) Patent Application Publication
(10) Pub. No.: US 2025/0167600 A1
(43) Pub. Date: May 22, 2025

(54) SIGNAL TRANSMISSION DEVICE FOR ANALOG CURRENT SIGNALS

(71) Applicant: Pepperl+Fuchs SE, Mannheim (DE)

(72) Inventor: Ulrich Behrens, Weinheim (DE)

(73) Assignee: Pepperl+Fuchs SE, Mannheim, OT (DE)

(21) Appl. No.: 18/949,271

(22) Filed: Nov. 15, 2024

(30) Foreign Application Priority Data
Nov. 16, 2023 (EP) 23210372.1

(51) Int. Cl. H02J 50/80; H02J 50/10; H02J 50/70

(52) U.S. Cl. CPC H02J 50/80; H02J 50/10; H02J 50/70

(57) ABSTRACT

A signal transmission circuit for an analog current signal in an explosion-protected area includes a transformer with one or a plurality of primary-side coils and one or a plurality of secondary-side coils coupled in a common magnetic circuit via a transformer yoke and a control circuit configured to control the voltage across the one or the plurality of secondary-side coils to zero by providing a compensation current for flux compensation. The control variable corresponds to a measuring voltage which is one of obtained in dependence on a voltage across a measuring coil arranged in the magnetic circuit; and obtained in dependence on a voltage across one of the plurality of secondary-side coils in the magnetic circuit when it is de-energized. The analog current signal corresponds to or is dependent on the compensation current.

### TECHNICAL FIELD

The invention relates to signal transmission devices for the transmission of analog current signals of a current loop interface having galvanic separation.

### TECHNICAL BACKGROUND

In process automation, analog signals are usually transmitted via current loop interfaces, which set a current of 0 mA or 4 mA to 20 mA depending on the analog signal to be transmitted. This form of analog signal transmission based on a variable current represents a very robust signaling standard, and is common in many areas of process automation.

However, in explosion-protected areas, it is necessary to provide galvanic isolation between a sensor module in the area of the measuring point and a control unit of a control center. Galvanic isolations are often implemented by transformers in the field of the signal transmission.

The current signal is transmitted by means of a transformer the primary side and secondary side of which have windings of an identical number of turns and opposite winding directions. With respect to an alternating current signal, the primary side and the secondary side carry the same current when the magnetic flux in the core is equal to zero.

To set the flux in the core to zero, such that a current flow results on the secondary side which corresponds to the current flow of the primary side, the voltage on the secondary side is controlled to 0 V by means of a control current. The control current of the control then corresponds to the primary-side current, i.e. the current signal.

Since the analog current signal to be transmitted can be a direct current signal or a very low-frequency signal, it is generally provided to provide a DC/AC conversion on the primary side and an AC/DC conversion on the secondary side of the transformer. In general, the DC/AC conversion takes place by periodically reversing the polarity, i.e. by applying the periodically reversed polarity current signal to the primary-side coil of the transformer by means of a primary-side inverter, and by respectively applying of the compensation current to the secondary-side coil by means of a secondary-side inverter. The primary-side inverters and the secondary-side inverters are generally operated in antiphase.

However, such an arrangement causes the parasitic properties of the semiconductor switches of the inverters and the parasitic ohmic resistances of the copper windings of the coils to distort the signal transmission.

It is therefore preferable to compensate for the parasitic influences. The parasitic influences can generally be compensated for by extensive measures, however, the corresponding compensations must be carried out separately for each signal transmission circuit, since the effects are generally non-linear. In addition, the parasitic influences are temperature-dependent, such that a temperature compensation must also be provided.

It is therefore an object of the present invention to provide an improved signal transmission circuit for a current signal of a current loop having a galvanic separation in which an additional compensation of the parasitic influences is not necessary.

### DISCLOSURE OF THE INVENTION

This object is achieved by the signal transmission circuit according to claim 1.

Further embodiments are set out in the dependent claims.

According to a first aspect, a signal transmission circuit for an analog current signal in an explosion-protected area is provided, comprising:
a transformer having one or a plurality (preferably two) of primary-side coils and one or a plurality (preferably two) of secondary-side coils which are coupled in a common magnetic circuit via a transformer yoke and, in particular, have identical numbers of turns;
a control circuit configured to control the voltage across the one or a plurality of secondary-side coils to zero by providing a compensation current for flux compensation, wherein the control variable corresponds to a measuring voltage which is one of:
   obtained depending on a voltage across a measuring coil arranged in the magnetic circle; and
   obtained depending on a voltage across one of the plurality of secondary-side coils in the magnetic circle if the coil is de-energized,
      wherein the analog current signal to be transmitted corresponds to or depends on the compensation current.

Furthermore, the signal transmission circuit can comprise a control unit and a first inverter, wherein the first inverter is controlled by the control unit to apply the analog current signal as a cyclic alternating current signal to the primary-side coil, or alternatively the first inverter is controlled by the control unit to apply the analog current signal alternately to one of the plurality of primary-side coils.

Furthermore, the measuring coil can be arranged in the magnetic circuit, and the signal transmission circuit can further comprise:
a second inverter which is controlled by the control unit to apply the compensation current cyclically alternately or cyclically with reversed polarity to the one or the plurality of secondary-side coils,
   wherein the control unit is configured to operate the first inverter and the second inverter cyclically in-phase or in antiphase, in particular with a switching frequency between 10 KHz and 350 KHz.

As described at the beginning, signal transmission circuits for current signals in explosion-protected areas can have inverters in which a first primary-side inverter converts a current signal of a current loop into an alternating current signal and applies it to the primary-side coil of a transformer. The secondary-side coil is connected to a second secondary-side inverter which is operated in antiphase to the first primary-side inverter such that the applied current signal acts on the transformer yoke in antiphase to the current signal applied to the primary side.

The inverters are usually configured as H-bridge circuits for cyclic pole reversal of the primary and/or secondary-side coils or as a two-way circuit for the alternating energization of one of the plurality of primary and/or the plurality of secondary-side coils, and are controlled by a suitable control unit. The inverters serve to convert a constant or low-frequency current signal into a periodic alternating current signal, and to transmit this signal by means of the transformer. A galvanic isolation is ensured by the transformer.

If the inverters are provided as a two-way circuit, they can be implemented by two alternating switches (semiconductor switches) and two coils connected in series. The center nodes of the two-way circuit can be a source or a sink for the signal current and/or the compensation current. The semiconductor switches of the two-way circuit are switched alternately. The alternating switching is carried out such that the flow direction in the magnetic circuit is reversed with each switching operation.

To transmit the current signal, a flux compensation is usually provided which continuously ensures by means of a control that the voltage across the secondary-side coil is 0 volts. Then—provided that the primary side and the secondary side have the same number of turns—the primary-side current through the primary-side coil corresponds to the secondary-side current of the secondary-side coil.

The flux compensation can use the secondary-side voltage as a control variable by injecting a compensation current that is continuously controlled such that the secondary-side voltage is set to 0 volts. However, this leads to current flows through the semiconductor switches of the second secondary-side inverter and the secondary-side coil, which are influenced by parasitic effects due to voltage drops across the ohmic resistance of the secondary-side coil and across the switched-on resistances of the switched-closed switched semiconductor switches of the second inverter. These are also usually compensated by the control circuit and lead to a compensation current which deviates from the primary-side current signal to be mapped. As a result, the current mirroring from the primary side to the secondary side is distorted, and a compensation of the parasitic influences on the transmitted current signal is necessary. Additionally, the ohmic resistance of the secondary-side coil and the switched-on resistance of the semiconductor switches are highly temperature-dependent, and compensating for this is also complex.

Furthermore, a third inverter can be provided to carry out the rectification of the voltage across the measuring coil.

The above signal transmission circuit for transmitting current signals of current loops therefore provides for an alternative for implementing the flux compensation to provide the transformer with a third coil, a measuring coil, which is connected to the control circuit via the third inverter to provide the measuring voltage as a control variable.

The third inverter can be controlled synchronously with the second inverter. The measuring coil is, like the secondary-side coil, inductively coupled to the primary-side coil via the transformer yoke, and thus supplies a voltage or a current at the connections thereof which depends on the flux through the transformer yoke.

However, the control circuit is configured to energize the secondary-side coil in such a way that the flux through the transformer yoke is compensated to zero. The control circuit is based on the measuring coil voltage which is rectified by the third inverter and measured in a de-energized state, and therefore parasitic effects which are caused by ohmic resistances have no influence on the flux compensation of the control circuit. Thus, a compensation for parasitic influences is not necessary, and a calibration of the signal transmission circuit can be omitted where appropriate. Also, the temperature influence is compensated for, since the flux through the measuring coil is controlled to zero.

In the case of a two-way circuit for controlling the plurality of secondary-side coils in the magnetic circuit according to a further alternative, the secondary-side coils are connected alternately into the current path by the control circuit, wherein the respective other coil remains de-energized. The respective de-energized secondary-side coil can be used for providing the measuring voltage.

In this regard, the control circuit can have an operational amplifier which controls the measuring voltage to 0 volts by providing a variable compensation current through the second inverter and the secondary-side coil to compensate for a voltage deviation of the measurement voltage from 0 volts, wherein the compensation current corresponds to the transmitted current signal.

Furthermore, the control circuit can have an amplifier semiconductor switch, in particular a bipolar transistor or a field-effect transistor, which is controlled by the signal at an output of the operational amplifier, wherein the amplifier semiconductor switch controls the level of the compensation current depending on the signal at the output of the operational amplifier.

To filter higher-frequency transient processes after the switching of the inverters, a low-pass filter can be provided which smoothes the control variable.

Furthermore, the control unit can be configured to operate the third inverter with a phase shift of between 0% and 50% of the period duration with respect to the operation of the second inverter.

Also, the switching times for the third inverter of the measuring coil can be delayed with respect to the control of the second inverter such that at least a part of the transient process after the switching of the semiconductor switches of the second inverter is suppressed, wherein the switching delay is between 0% and 50% of the period duration of the cyclic operation of the inverters.

Furthermore, the energy in the leakage inductances can have a significant influence on the transmission of the current signal. This generally expresses itself by transient processes, which can be rendered harmless by appropriate switching measures. Such measures may be attenuators, such as R-C combinations or selective suppression.

Furthermore, the inverters can each be implemented by an H-bridge circuit, which is respectively implemented by two inverter circuits each. The center nodes of the inverter circuits are connected to each other via the respective coil. The semiconductor switches are switched alternately. The alternating switching takes place in such a way that the current direction in the coils arranged between the center nodes of the serially connected semiconductor switches is reversed with each switching operation.

In particular, the cyclic operation of the inverters can be provided without switching gaps or with an overlap of the switched-on phases of the semiconductor switches of at least one of the inverter circuits.

As a rule, switching gaps are provided for the switching of such an inverter to avoid a short-circuit current phase through the inverter circuits or simultaneous switching-on of the switches in the two-way circuit upon occurrence of switching delays. These switching gaps may cause the compensation current to exceed the current value of the current signal. However, since the current signal is continuously applied, the energy introduced during the switching gap is added to the mean value of the current signal and has therefore to be compensated with a corresponding compensation current. To avoid this effect, it can be provided to operate the inverters or the two-way circuit without a switching gap and, if necessary, to allow or to permit an overlap of the switched-on phases (while the semiconductor switches are closed) of the semiconductor switches, e.g. for up to 5% of the period duration during which semiconductor switches of a inverter branch of the secondary-side coil are briefly closed, which has no influence on the transmission of the current signal, since the voltage across the secondary-side coil is controlled to 0 volts anyway.

### BRIEF DESCRIPTION OF THE DRAWINGS

Embodiments are explained in more detail below with reference to the accompanying drawings, wherein:

FIG. 1 shows a schematic representation of the signal transmission circuit according to an embodiment;

FIG. 2 shows a schematic representation of a signal transmission circuit according to another embodiment; and

FIG. 3 shows a schematic representation of a signal transmission circuit according to yet another embodiment.

Similar reference signs refer to elements of similar or comparable function.

### DESCRIPTION OF EMBODIMENTS

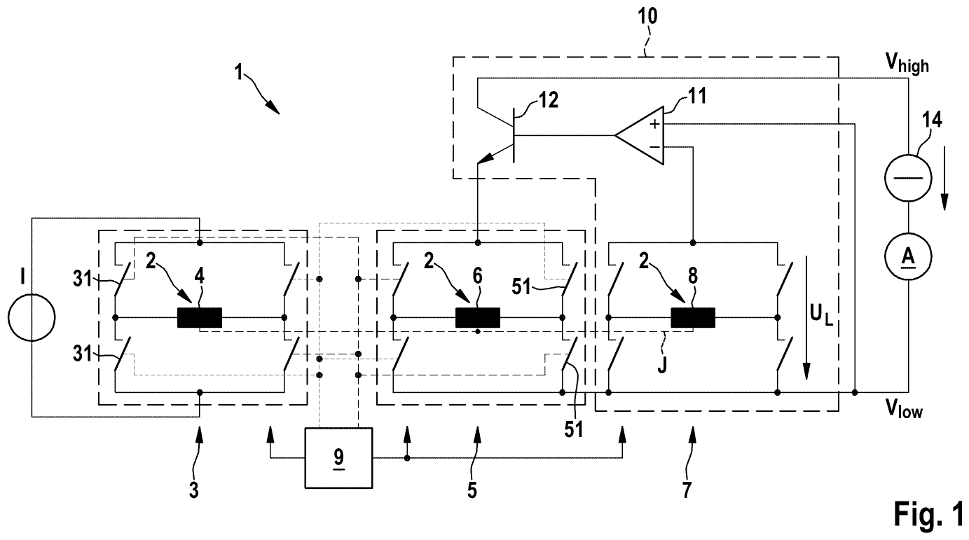

FIG. 1 shows a circuit diagram for a signal transmission circuit 1 for transmitting a current signal. The current signal I can be a current signal, which is common in process automation, of a current loop between 0 mA or 4 mA to 20 mA. The current signal I corresponds to an analog signal with which an analog variable can be transmitted. In the explosion-protected area, it is necessary to electrically isolate the lines for transmitting the current signal from the explosion-protected area.

Therefore, the signal transmission circuit 1 is intended to transmit current signals by means of a transformer 2. The transformer 2 is provided with a primary-side coil 4 and a secondary-side coil 6, which are coupled to one another in a magnetic circuit via a transformer yoke J. The primary-side coil 4 and the secondary-side coil 6 preferably have the same number of turns and are wound in opposite directions.

Since the current signal is usually continuously applied and changes only at low frequency, a first inverter 3 is provided for the primary-side coil 4, and a second inverter 5 is provided for the secondary-side coil 6. These serve to convert the low-frequency current signal into an alternating current signal to ensure the transmission of the signal information via the transformer 2.

The inverters 3, 5 are configured as H-bridge circuits and have two inverter paths consisting of serially connected semiconductor switches 31, 51, the center nodes M of which are connected to one another via the respective coil 4, 6. By alternately switching the semiconductor switches 31, 51, the polarity of the interconnection of the respective coil 4, 6 can be periodically reversed, such that a corresponding signal transmission via the transformer 2 is possible.

The first inverter 3 and the second inverter 5 are usually operated in phase or in antiphase, such that the second inverter 5 impresses the same current signal on the transformer 2 as the first inverter 3. The semiconductor switches 31, 51 are controlled at a predetermined switching frequency of between 10 KHz and 350 kHz by means of a control unit 9 or the like.

A control circuit 10 is provided to control the voltage across the secondary-side coil 8. For this purpose, the control circuit 10 has an operational amplifier 11 and an amplifier semiconductor switch 12, in particular a bipolar transistor or field-effect transistor, which is controlled by the signal at an output of the operational amplifier 11. For this purpose, the output of the operational amplifier 11 controls a control terminal (base terminal or gate terminal) of the amplifier semiconductor switch 12.

The amplifier semiconductor switch 12 is connected between a supply voltage source 14 and the second inverter 5 having the secondary-side coil 6, such that a current through the second inverter 5 is set variably. The supply voltage source 14 provides a constant supply voltage between a high supply potential V_{high} and a low supply potential V_{low}. The current through the supply voltage source 14 represents the transmitted current signal.

The non-inverting input of the operational amplifier 11 is connected to the low supply potential V_{low}, which indicates a reference potential or a potential of 0 V. The inverting input of the operational amplifier 11 is connected to a flux-dependent measuring voltage.

The measuring voltage is detected via a third coil, the measuring coil 8, which is arranged in the magnetic circuit of the transformer 2. A third inverter 7 is assigned to the measuring coil 8 to rectify the voltage induced in the measuring coil 8 and to provide it as a measuring voltage. To do this, the third inverter 7 is synchronously controlled to the second inverter 5.

The third inverter 7 is switched between the low supply potential (reference potential) and the inverting input of the operational amplifier 11.

The amplifier semiconductor switch 12 is switched between a supply voltage source 14 and the second inverter 5 with the secondary-side coil 6, such that the output of the operational amplifier 11 controls the current flow through the secondary-side coil 6 depending on a voltage difference across the measuring coil 8. If a magnetic flux occurs in the transformer yoke, the measuring voltage, which corresponds to the rectified voltage across the measuring coil 8, changes to a non-zero value, and a control intervention is carried out via the operational amplifier 11 and the amplifier semiconductor switch 12 by injecting a current into the secondary-side coil 6, such that the voltage across the measuring coil 8 is controlled to zero. The current required to do this essentially corresponds to the current signal of the primary side of the transformer 2.

To eliminate effects from transient processes, the control signal for the control of the third inverter 7 can be delayed by up to 50% with respect to the control of the second inverter 5.

Alternatively, or additionally, a low-pass filter can be provided between the third inverter 7 and the inverting input of the operational amplifier, which only passes a DC component of the measuring voltage to the operational amplifier 11.

Furthermore, leakage inductances can be eliminated in a suitable manner. Suitable means for the neutralization of the leakage inductances are attenuators having RC combinations or sampling delays upon detecting the voltage across the measuring coil 8.

Generally, inverters, which are constructed in the form of H-bridge circuits, are operated with switching gaps to avoid short circuits via the inverter paths of the bridge circuit. However, this leads to an increase of the compensation current through the amplifier semiconductor switch 12. Since an energy transfer via the transformer 2 is prevented by means of the flux compensation, the second inverter 5 and the third inverter 7 can be operated without switching gaps, in particular, a switching overlap can be provided which briefly allows a short-circuit path via at least one of the inverter paths. This overlap can be between 0% and 5%. Since the voltage across the secondary-side coil 6 and the measuring coil 8 is controlled to 0 V, the short circuit in one of the inverter paths of the inverters 5, 7 cannot lead to a significant current flow.

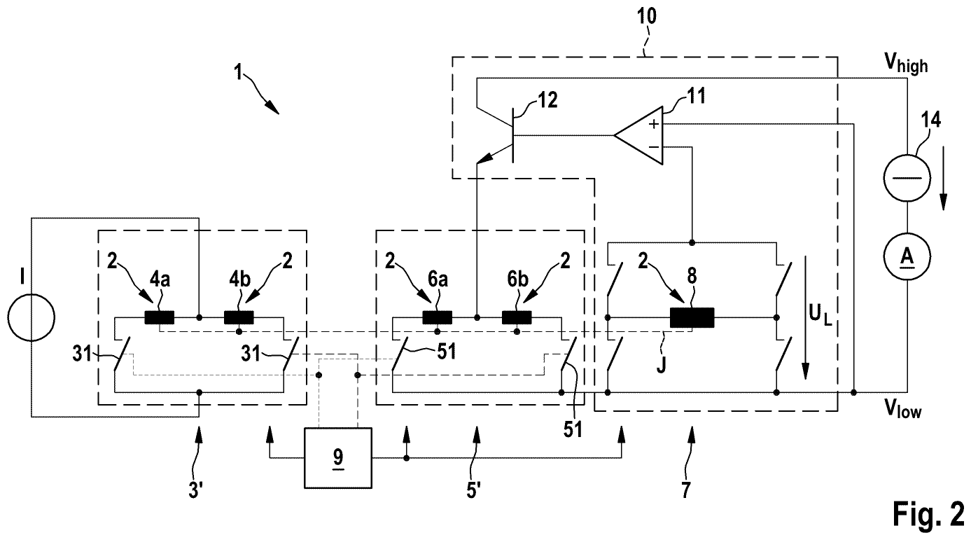

FIG. 2 illustrates a further embodiment of the signal transmission circuit. In contrast to the embodiment of FIG. 1, the inverters 3′, 5′ are not configured as H-bridge circuits, but as two-way circuits which are controlled by the control unit 9 to switch one of two primary-side coils 4a, 4b and one of two secondary-side coils 6a, 6b into the current path and to disconnect the respective other one from it. The two primary-side coils 4a, 4b and the two secondary-side coils 6a, 6b are arranged in the same magnetic circuit by means of the transformer yoke. Each of the coils is serially connected with a semiconductor switch and can thus be separated from the current path.

The control of the inverters 3′, 5′ is done by means of the measuring coil 8 and the third inverter 7 analogous to the embodiment of FIG. 1. It may also be provided to form one of the inverters as an H-bridge circuit for controlling only one coil and the other of the inverters as a two-way circuit for controlling two coils.

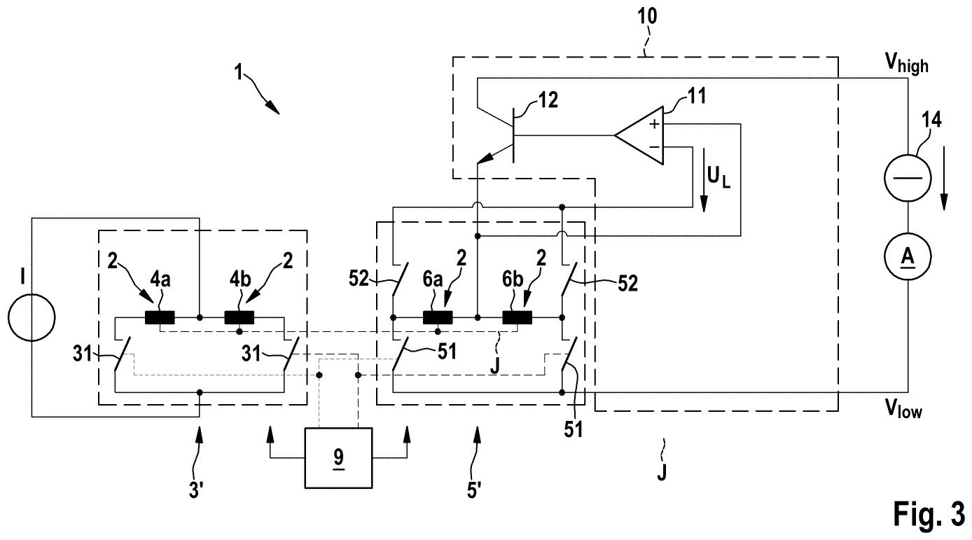

FIG. 3 shows a further embodiment of the signal transmission circuit. As in the embodiment of FIG. 2, the second inverter 5′ is configured as a two-way circuit that is controlled by the control unit 9. The first inverter 3 can be configured as an H-bridge circuit for controlling only one primary-side coil or as a two-way circuit for controlling two primary-side coils 4a, 4b.

The nodes between the secondary-side coils 6a, 6b and the respective semiconductor switches of the second inverter 5′ are connected to the inverting input of the operational amplifier 11 via additional semiconductor switches 52. The inverters are controlled by the control unit 9 in the manner described above. The additional semiconductor switches 52 are controlled by the control unit 9 to connect the de-energized secondary-side coil 6a, 6b to the operational amplifier and to disconnect the other one from it.

1. A signal transmission circuit for an analog current signal in an explosion-protected area, comprising:
a transformer having one or a plurality of primary-side coils and one or a plurality of secondary-side coils which are coupled in a common magnetic circuit via a transformer yoke; and
a control circuit configured to control the voltage across the one or the plurality of secondary-side coils to zero by providing a compensation current for flux compensation, wherein the control variable corresponds to a measuring voltage which is one of:
obtained depending on a voltage across a measuring coil arranged in the magnetic circuit; and
obtained depending on a voltage across one of the plurality of secondary-side coils in the magnetic circuit when it is de-energized,
wherein the analog current signal to be transmitted corresponds to or depends on the compensation current.

2. The signal transmission circuit according to claim 1, further comprising:
a control unit; and
a first inverter controlled by the control unit to apply the analog current signal as a cyclic alternating current signal to the one or the plurality of primary-side coils.

3. The signal transmission circuit according to claim 1, further comprising:
a control unit; and
a first inverter controlled by the control unit to apply the analog current signal alternately to one of the plurality of primary-side coils.

4. The signal transmission circuit according to claim 2, wherein the measuring coil is arranged in the magnetic circuit and the signal transmission circuit further comprises:
a second inverter, which is controlled by the control unit to cyclically reverse the polarity of the compensation current or to cyclically apply it alternately to the one or the plurality of secondary-side coils,
wherein the control unit is configured to operate the first inverter and the second inverter cyclically in phase or in antiphase, in particular at a switching frequency between 10 kHz and 350 kHz.

5. The signal transmission circuit according to claim 4, wherein a third inverter is provided to rectify the voltage across the measuring coil.

6. The signal transmission circuit according to claim 5, wherein the control unit is configured to operate the third inverter in phase with or synchronously to the second inverter.

7. The signal transmission circuit according to claim 5, wherein the control unit is configured to operate the third inverter with a phase shift of between 0% and 50% of the period duration with respect to the operation of the second inverter.

8. The signal transmission circuit according to claim 7, wherein the switching times for the third inverter of the measuring coil are delayed with respect to the controlling of the second inverter in such a way that at least a part of the transient process after the switching of the semiconductor switches of the second inverter is suppressed, wherein the switching delay is between 0% and 50% of the period of the cyclic operation of the inverters.

9. The signal transmission circuit according to claim 1, wherein a plurality of secondary-side coils are provided in the magnetic circuit, which are alternately switched by means of a second inverter into the current path by the control circuit, wherein the respective de-energized secondary-side coil is used to provide the measuring voltage.

10. The signal transmission circuit according to claim 1, wherein the one or the plurality of primary-side coils, and the one or the plurality of secondary-side coils, which are simultaneously current-carrying, have identical numbers of turns.

11. The signal transmission circuit according to claim 1, wherein the control circuit has an operational amplifier which controls the measuring voltage to 0 volts by equalizing a voltage deviation of the measuring voltage from 0 volts by providing a variable compensation current through the second inverter and the secondary-side coil, wherein the compensation current corresponds to the transmitted current signal.

12. The signal transmission circuit according to claim 11, wherein the control circuit comprises an amplifier semiconductor switch, in particular a bipolar transistor or field effect transistor, which is controlled by the signal at an output of the operational amplifier, wherein the amplifier semiconductor switch controls the level of the compensation current depending on the signal at the output of the operational amplifier.

13. The signal transmission circuit according to claim 1, wherein the inverters are configured as H-bridge circuits including inverter circuits or as a two-way circuit including at least two semiconductor switches each, wherein the cyclic operation of the inverters is provided without switching gaps or with an overlap of the switched-on phases of the semiconductor switches of at least one of the inverter circuits or of the two-way circuit.

14. The signal transmission circuit according to claim 1, wherein the measuring voltage is low-pass filtered.

15. The signal transmission circuit according to claim 3, wherein the measuring coil is arranged in the magnetic circuit and the signal transmission circuit further comprises:
a second inverter, which is controlled by the control unit to cyclically reverse the polarity of the compensation current or to cyclically apply it alternately to the one or the plurality of secondary-side coils,
wherein the control unit is configured to operate the first inverter and the second inverter cyclically in phase or in antiphase, in particular at a switching frequency between 10 kHz and 350 kHz.

16. The signal transmission circuit according to claim 15, wherein a third inverter is provided to rectify the voltage across the measuring coil.

17. The signal transmission circuit according to claim 16, wherein the control unit is configured to operate the third inverter in phase with or synchronously to the second inverter.

18. The signal transmission circuit according to claim 16, wherein the control unit is configured to operate the third inverter with a phase shift of between 0% and 50% of the period duration with respect to the operation of the second inverter.

19. The signal transmission circuit according to claim 18, wherein the switching times for the third inverter of the measuring coil are delayed with respect to the controlling of the second inverter in such a way that at least a part of the transient process after the switching of the semiconductor switches of the second inverter is suppressed, wherein the switching delay is between 0% and 50% of the period of the cyclic operation of the inverters.
